(19) United States
(12) Patent Application Publication
(10) Pub. No.: US 2009/0004804 A1
(43) Pub. Date: Jan. 1, 2009

(54) METHOD OF FABRICATING SEMICONDUCTOR DEVICES

(76) Inventor: Yong-Ho Oh, Bupyeong-gu (KR)

Correspondence Address: SHERR & VAUGHN, PLLC, 620 HERNDON PARKWAY, SUITE 200, HERNDON, VA, 20170, US

(21) Appl. No.: 12/143,866

(22) Filed: Jun. 23, 2008

(30) Foreign Application Priority Data
Jun. 26, 2007 (KR) 10-2007-0062635

(51) Int. Cl. H01L 21/336

(52) U.S. Cl. 438/290; 257/E21.409

(57) ABSTRACT

A method of fabricating a semiconductor device may include forming a well in a semiconductor substrate, and then forming a gate oxide on and/or over the semiconductor substrate, and then forming a gate on and/or over the gate oxide, and then forming a pocket under the gate, and then performing a first spike anneal on the semiconductor substrate, and then performing a deep source/drain implant process on the semiconductor substrate, and then performing a second spike anneal on the semiconductor substrate.

The present application claims priority under 35 U.S.C. §119 to Korean Patent Application No. 10-2007-0062635 (filed on Jun. 26, 2007), which is hereby incorporated by reference in its entirety.

### BACKGROUND

As a gate length of a Complementary Metal-Oxide Semiconductor Field Effect Transistor (CMOSFETC) device became shortened below 90 nm, technologies for enhancing the performance of such devices and to reduce power consumption have been researched. However, many semiconductor manufacturers depend on technology of advanced companies because of difficulty of technology development and considerable technology development expenses etc.

### SUMMARY

Embodiments relate to a method of fabricating a semiconductor device which can enhance device performance using simplifying processes.

Embodiments relate to a method of fabricating a semiconductor device that may include at least one of the following steps: forming a well in a semiconductor substrate; and then forming a gate oxide on and/or over the semiconductor substrate; and then forming a gate on and/or over the gate oxide; and then forming a pocket under the gate; and then performing a first spike anneal to the semiconductor substrate; and then performing a deep source/drain implant process to the semiconductor substrate; and then performing a second spike anneal to the semiconductor substrate.

Embodiments relate to a method that may include at least one of the following steps: forming a well in a semiconductor substrate; and then forming a gate structure on the semiconductor substrate; and then forming a pocket under the gate structure; and then performing a first spike anneal on the semiconductor substrate; and then performing a deep source/drain implant process on the semiconductor substrate by sequentially implanting a first plurality of phosphorus ions, a plurality of arsenic ions and a second plurality of phosphorus ions in an NMOS area of the semiconductor substrate and sequentially implanting a first plurality of boron ions and a second plurality of boron ions in a PMOS area of the semiconductor substrate; and then performing a second spike anneal on the semiconductor substrate.

Embodiments relate to a method that may include at least one of the following steps: forming a well in a semiconductor substrate; and then forming a gate structure on the semiconductor substrate; and then performing a gate pre-doping by implanting ions of a first-type dopant into an NMOS area of the semiconductor substrate; and then forming a pocket under the gate structure; and then performing a first spike anneal on the semiconductor substrate; and then performing a deep source/drain implant process on the semiconductor substrate by sequentially implanting ions of the first-type dopant, ions of a second of a second-type dopant and ions of the first-type dopant in the NMOS area and sequentially implanting ions a third-type dopant and ions of the third-type dopant in a PMOS area of the semiconductor substrate; and then performing a second spike anneal on the semiconductor substrate.

### DRAWINGS

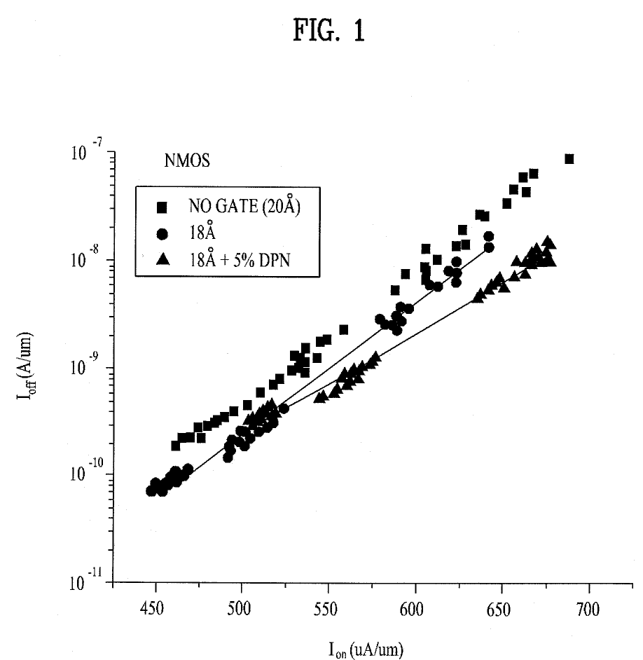

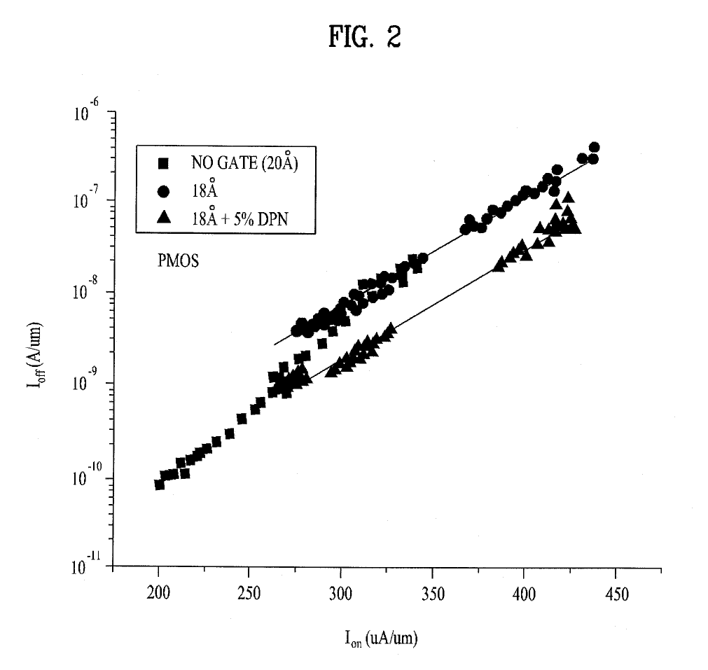

Example FIGS. 1 and 2 illustrate Iₒₙ-I_{off} characteristic of a device in applying a plasma nitridation to NMOS and PMOS, in accordance with embodiments.

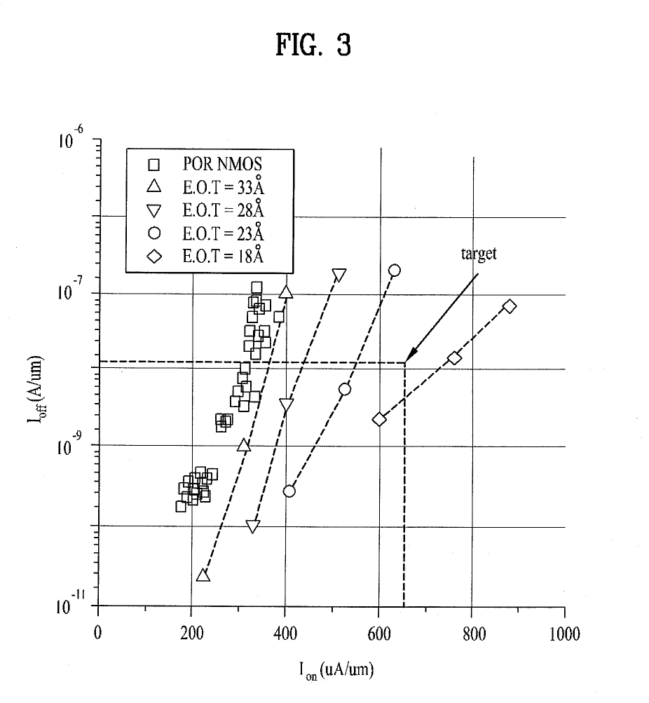

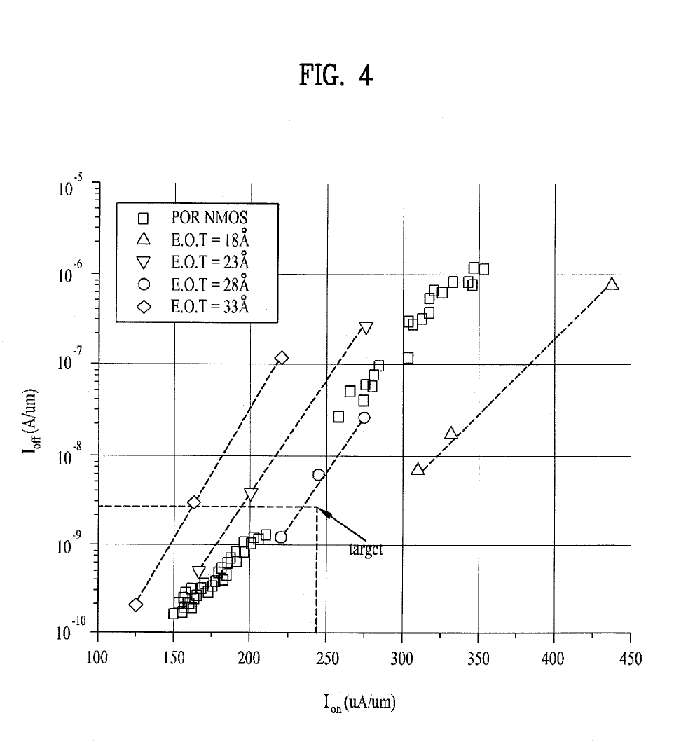

Example FIGS. 3 and 4 illustrate a comparison between a simulation result and a measurement result for an actual lot for Iₒₙ-I_{off} characteristic in NMOS and PMOS, in accordance with embodiments.

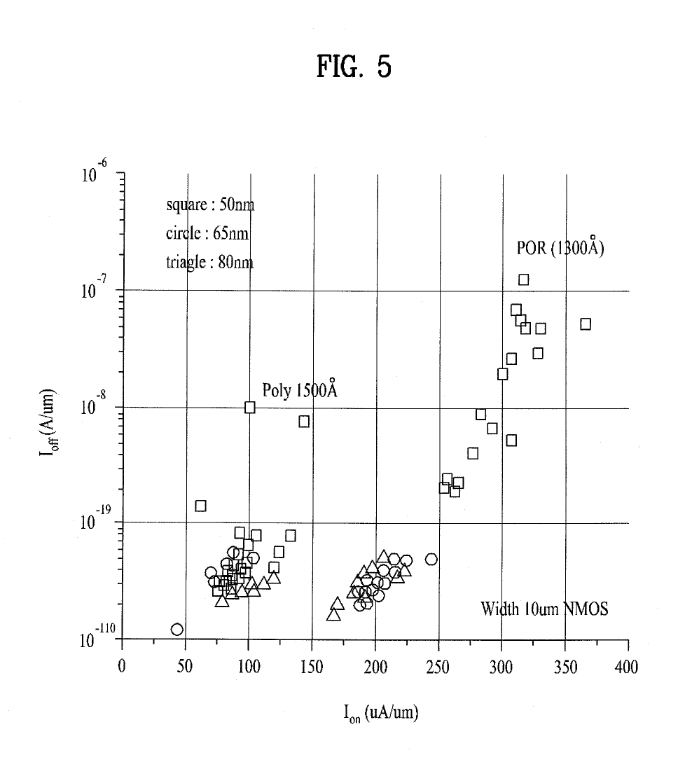

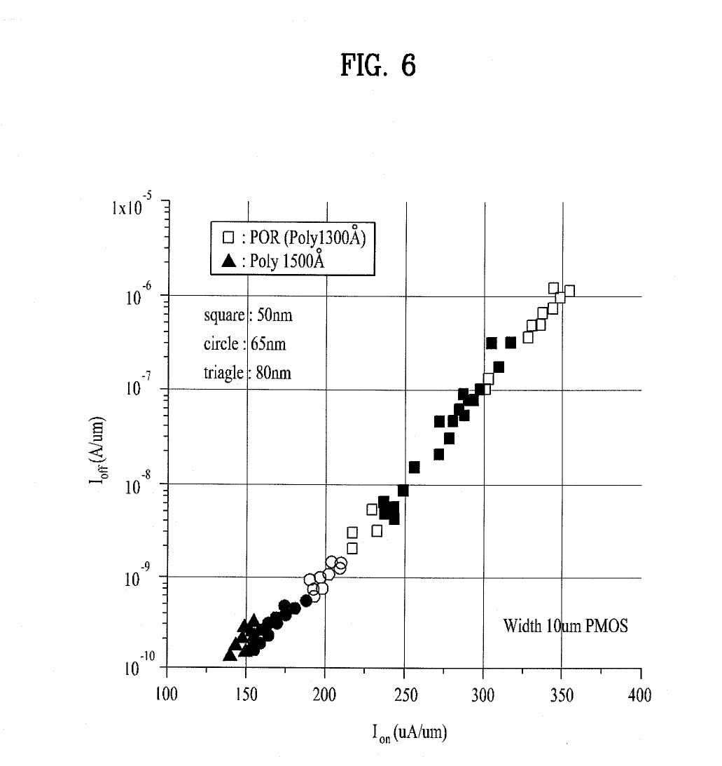

Example FIGS. 5 and 6 illustrate Iₒₙ-I_{off} characteristics of NMOS and PMOS based on a gate poly thickness, in accordance with embodiments.

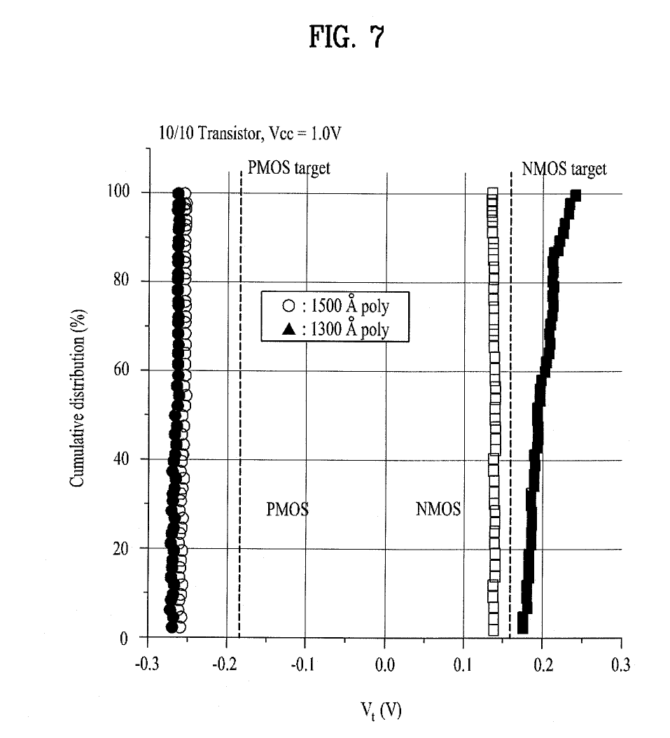

Example FIG. 7 illustrates a threshold voltage distribution of a long channel device based on a gate poly thickness, in accordance with embodiments.

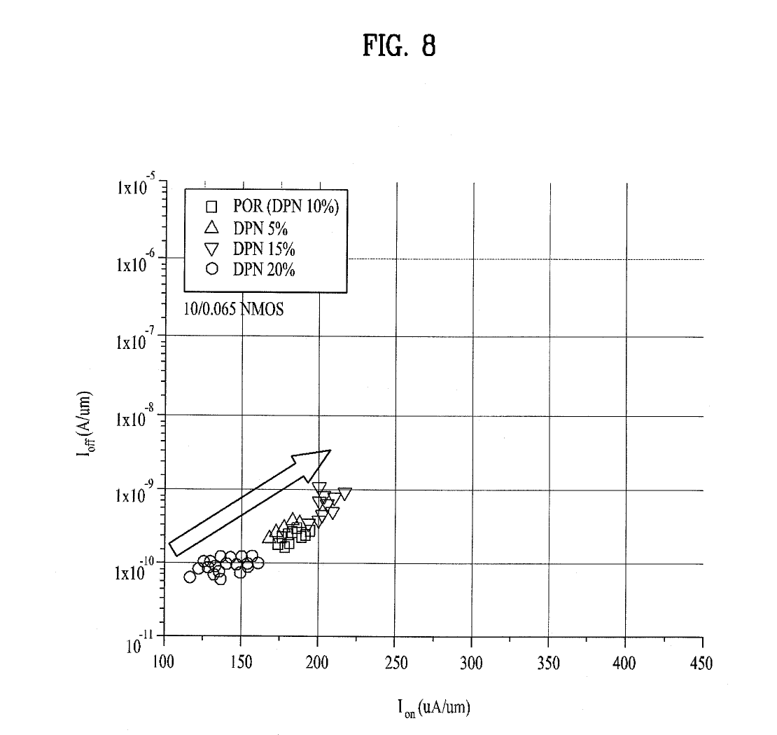

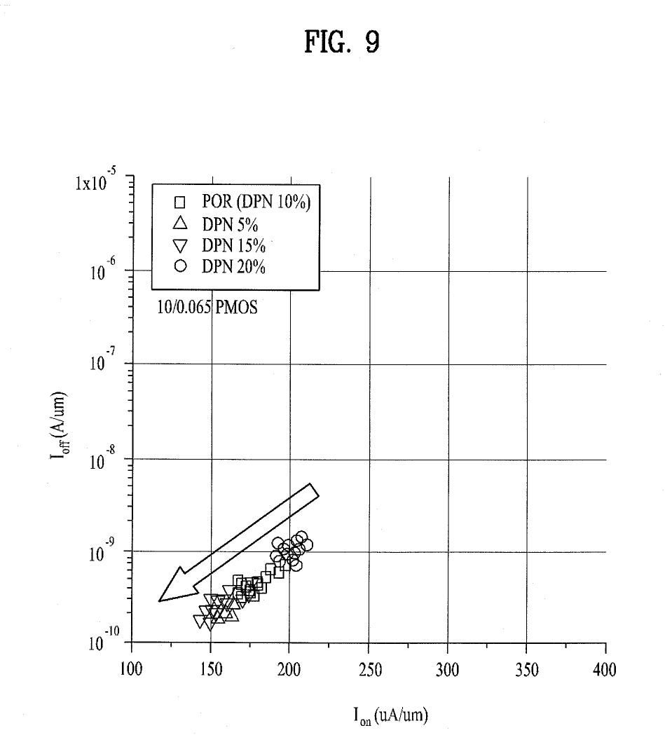

Example FIGS. 8 and 9 illustrate Iₒₙ-I_{off} characteristics of NMOS and PMOS based on a nitrogen content in a plasma nitridation process DPN, in accordance with embodiments.

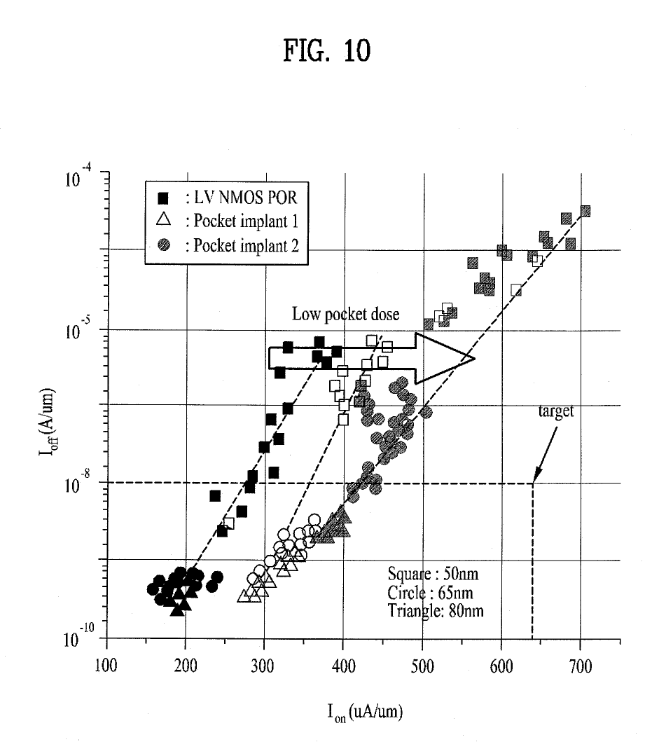

Example FIG. 10 illustrates Iₒₙ-I_{off} characteristic of a device based on an implant dose in a pocket implant process, in accordance with embodiments.

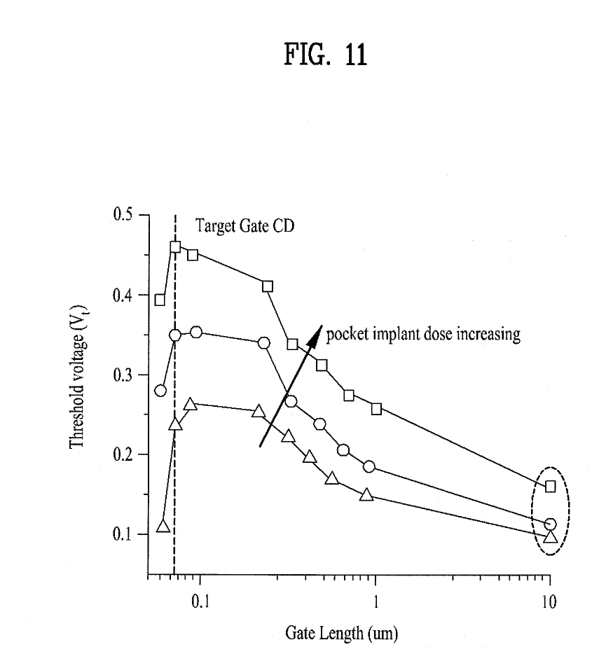

Example FIG. 11 represents a Vₜ roll-off characteristic of a device based on an implant dose in a pocket implant process, in accordance with embodiments.

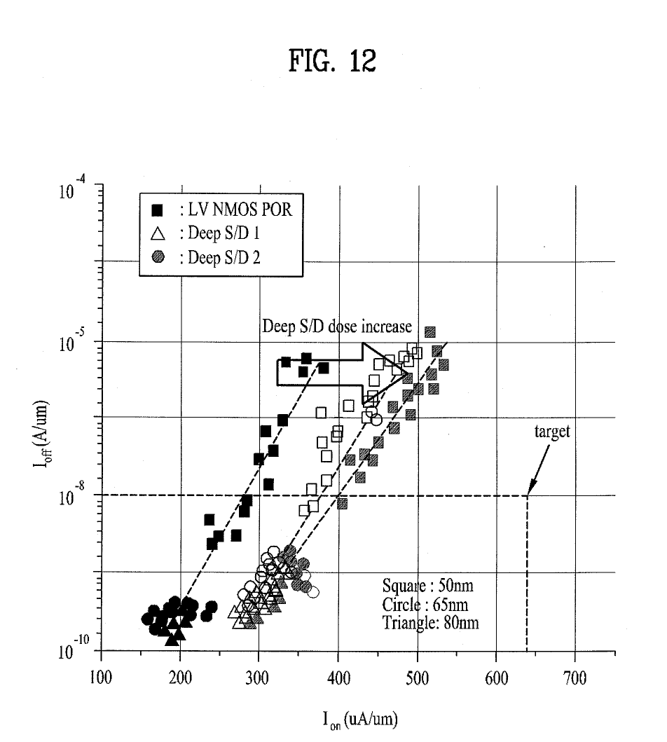

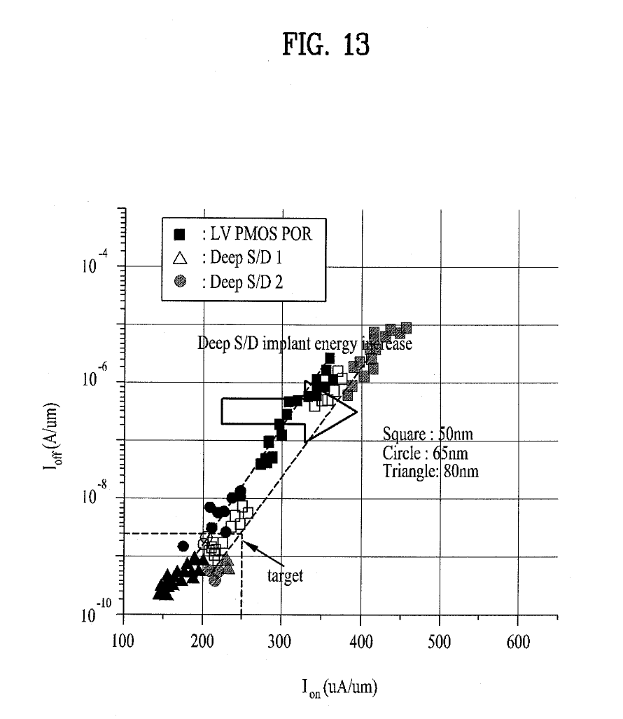

Example FIGS. 12 and 13 illustrate Iₒₙ-I_{off} characteristic of a device based on deep S/D implant dose and deep S/D implant energy in a deep S/D implant process for NMOS and PMOS, in accordance with embodiments.

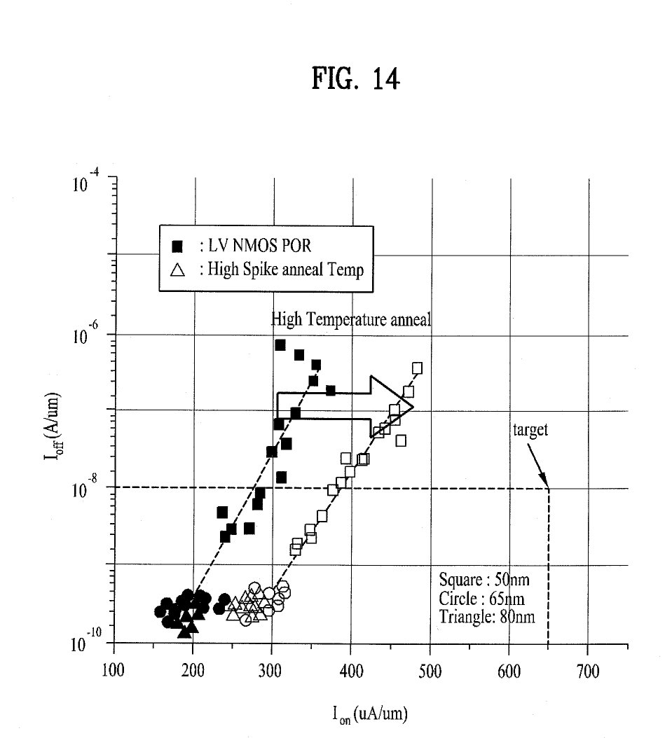

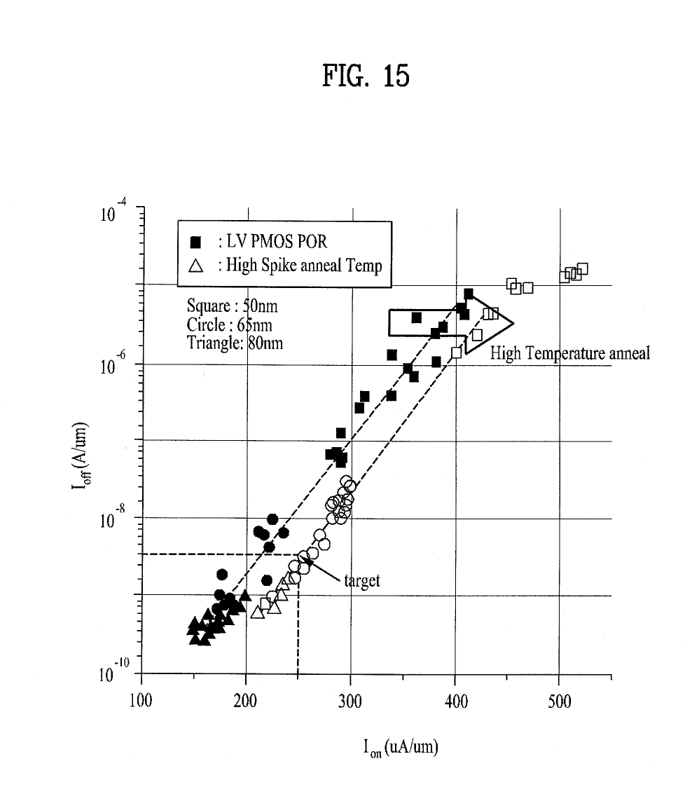

Example FIGS. 14 and 15 illustrate Iₒₙ-I_{off} characteristic of NMOS and PMOS by temperature of spike anneal process, in accordance with embodiments.

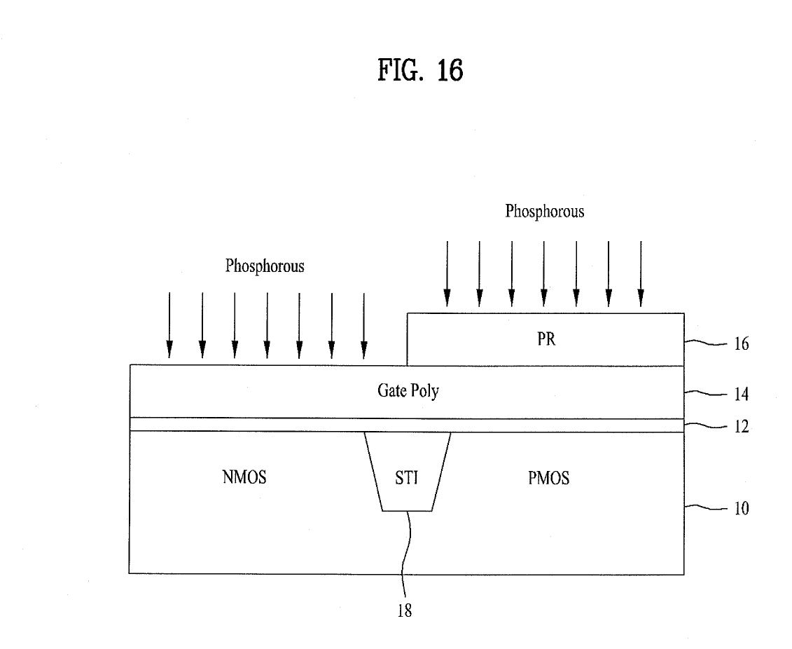

Example FIG. 16 illustrates a gate pre-doping process for a device performance improvement of NMOS, in accordance with embodiments.

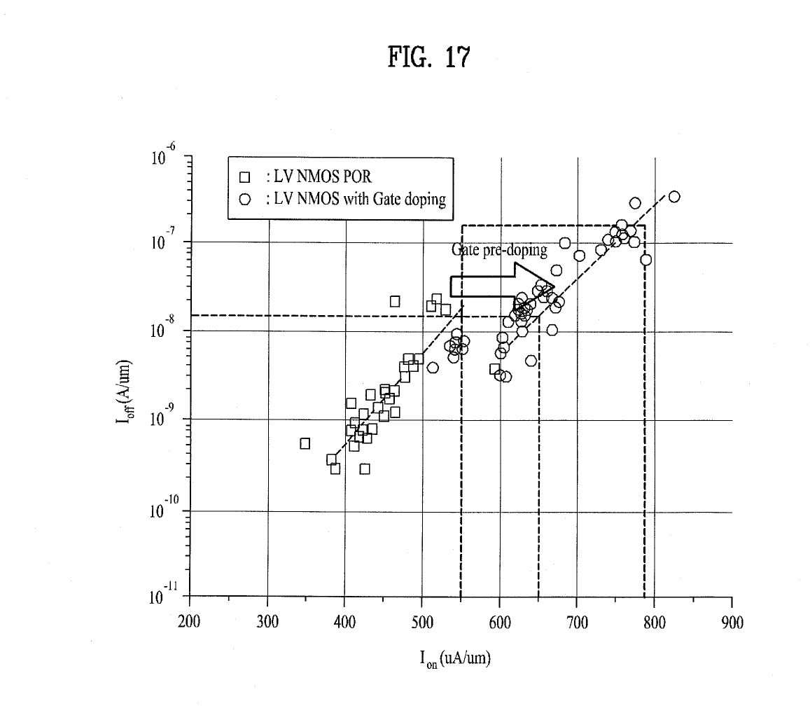

Example FIG. 17 illustrates Iₒₙ-I_{off} characteristic comparison for NMOS to which gate pre-doping process is applied and NMOS to which the gate pre-doping process is not applied, in accordance with embodiments.

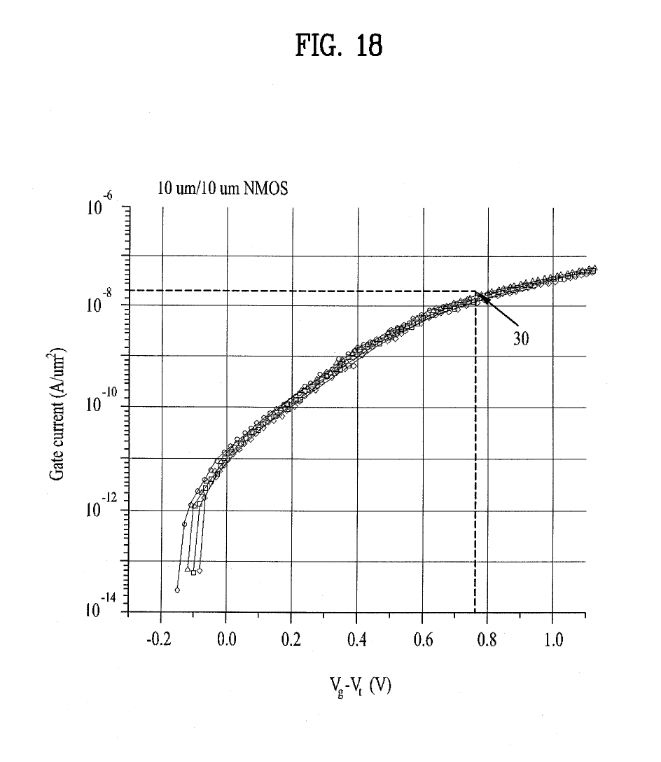

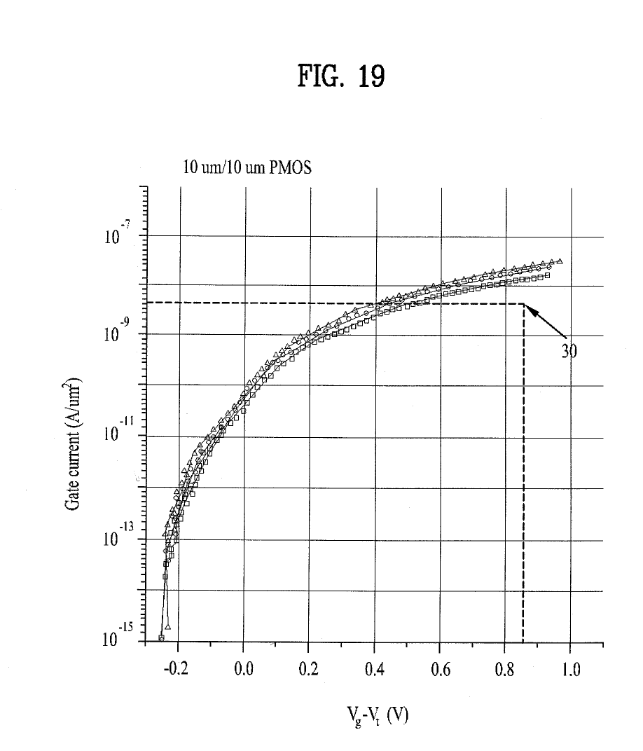

Example FIGS. 18 and 19 illustrate a measurement result of gate leakage current in 90 nm generic logic transistor for NMOS and PMOS, in accordance with embodiments.

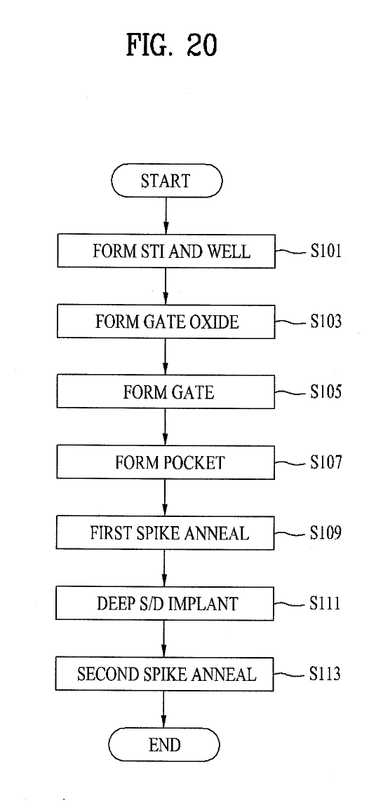

Example FIG. 20 illustrates a flowchart for a semiconductor device fabrication method in accordance with embodiments.

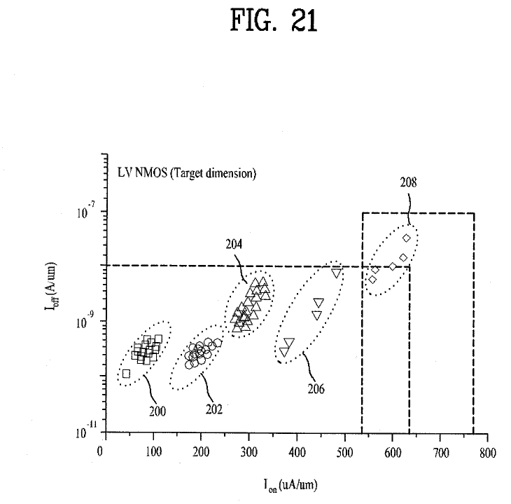

Example FIG. 21 illustrates performance of NMOS manufactured in a semiconductor device fabrication method in accordance with embodiments.

### DESCRIPTION

In the description of the embodiment, when each layer (film), an area, a pattern or structures are described to be formed “on/above/over/upper” or “down/below/under/lower” each layer (film), the area, the pattern or the structures, it can be understood as the case that each layer (film), an area, a pattern or structures are formed by being directly contacted to each layer (film), the area, the pattern or the structures and it can further be understood as the case that other layer (film), other area, other pattern or other structures are additionally formed therebetween. Therefore, the meanings should be judged according to the technical idea of the embodiment.

In accordance with embodiments, various measurements are performed by varying process conditions of ion implant process and anneal process to improve an electrical characteristic of semiconductor device. Before processing an actual lot, a simulation for a determination of ion implant process condition is performed with considering the size of 90 nm generic logic transistor and an electrical characteristic change of devices based on a plasma nitridation process and a spike anneal process. Based on the ion implant process condition obtained through the simulation, the electrical characteristic of device is confirmed and an optimized experiment for an ion implant process condition and a subsequent anneal process condition is performed, for improving performance of the device. A determination of ion implant process condition, an optimization process to the ion implant process and the subsequent anneal process, and a change of device performance based thereon are described in detail through the simulation as follows.

In accordance with embodiments, to increase characteristics of a device, an optimizatioin for gate stack, process condition of pocket implant, deep source/drain implant and a spike anneal may be obtained. The determination for a plasma nitridation process and an ion implant process condition through a simulation is first described as follows. In accordance with embodiments, an evaluation of the plasma nitridation and a performance change of a device therefor are appreciated to develop a 90 nm generic logic transistor process. In the plasma nitridation, a higher nitrogen content as compared with the existing thermal nitridation may be added to a gate oxide. Through such s process, an equivalent oxide thickness (E.O.T.) can be effectively lowered. To get a performance change of device based on the plasma nitridation, a plasma nitridation is applied to an existing 0.13 μm logic transistor process.

Example FIGS. 1 and 2 each provide Iₒₙ-I_{off} characteristics of a device in applying a plasma nitridation to NMOS and PMOS. Iₒₙ indicates a current between drain and source in a channel formation. I_{off} indicates a current between drain and source in a non-formation of channel. “NO GATE” denotes a gate formed of nitride-oxide, and 20 Å and 18 Å each indicate thickness of gates. 5% DPN denotes a decoupled plasma nitridation (DPN) with a nitrogen content of 5%. designates a plasma nitridation is not performed while ▴ indicates a plasma nitridation is performed.

As illustrated in example FIGS. 1 and 2, when NMOS and PMOS have the same thickness of the gate oxide, and when the plasma nitridation is applied, an Iₒₙ-I_{off} characteristic of a device in all the NMOS and PMOS is enhanced. That is, when the plasma nitridation is applied to the gate oxide of the NMOS and PMOS, an equivalent oxide thickness (E.O.T.) can be effectively lowered in the same gate oxide thickness. With such a result, a simulation for a determination of ion implant process condition may be performed. In performing the simulation, plasma nitridation, a remaining oxide structure in a formation of a sidewall spacer and a spike anneal process, etc. may be considered. Through the simulation, conditions for a channel implant, pocket implant (here, pocket may mean halo), lightly doped drain (LDD) implant and deep S/D implant processes can be predetermined. The following example Table 1 determined through the simulation provides an ion implant process and an anneal process of a 90 nm logic transistor in accordance with embodiments.

TABLE 1

| Se- | | |
|---|---|---|
| quence | NMOS | PMOS |
| Well | B, 204~276 KeV, | P, 380~520 KeV, pf.450 KeV, |
| | pf.240 KeV, 1.5E13~2.3E13, | 0.85E13~1.15E13, pf.1.0E13 |
| | pf.2.0E13 | |
| | B, 76~104 KeV, pf.90 KeV, | P, 187~253 KeV, pf.220 KeV, |
| | 1.2E13~1.8E13, pf.1.5E13 | 0.85E13~1.15E13, pf.1.0E13 |
| Channel | B, 17~23 KeV, pf.20 KeV, | As, 85~115 KeV, pf.100 KeV, |
| | 3.0E12~4.2E12, pf.3.6E12 | 4.6E12~6.4E12, pf.5.5E12 |
| | (tilt angle: 7°) | (tilt angle: 7°) |
| CNH | B, 17~23 KeV, pf.20 KeV, | |
| | 6.1E12~8.3E12, pf.7.2E12 | |
| | (tilt angle: 7°) | |

Well anneal, 820~1260° C., pf.1095° C., 17~23 sec, pf.20 sec

| | | |
|---|---|---|
| Pocket | BF2, 42~58 KeV, pf.50 KeV, | As, 50~70 KeV, pf.60 KeV, |
| | 3.4E13~4.8E13, pf.4.1E13 | 1.9E13~2.7E13, pf.2.3E13 |
| | 27~33 deg, pf.30 deg. | 36~44deg. pf.40 deg. |
| | Tilt (4R) | Tilt (4R) |
| LDD | As, 1.7~2.3 KeV, pf.2 KeV, | BF2, 1.2~1.8 KeV, pf.1.5 KeV, |
| | 8.1E14~11.1E14, pf.9.6E14 | 4.6E14~6.4E14, pf.5.5E14 |

LN Anneal:Spike, 750~1250° C., pf.1000° C.
SW anneal:Spike, 710~1093° C., pf.950° C.

| | | |
|---|---|---|
| Deep | P, 25~35 KeV, pf.30 KeV, | B, 8.5~11.5 KeV, pf.10 KeV, |
| S/D | 5.1E13~6.9E13, pf.6.0E13 | 4.2E13~5.8E13, pf.5.0E13 |
| | As, 25~35 KeV, pf.30 KeV, | B, 3.4~4.6 KeV, pf.4 KeV, |
| | 1.6E15~2.3E15, pf.2.0E15 | 2.2E15~3.0E15, pf.2.6E15 |
| | P, 6.5~9.5 KeV, pf.8 KeV, | |
| | 0.85E15~1.15E15, pf.1.0E15 | |

XP Anneal:Spike, 1000~1100° C., pf.1050° C.

As illustrated in example Table 1, “Well” indicates an implant for a well, “Channel” indicates an implant for a channel of a low voltage (LV) transistor, “CHN” indicates an implant for a channel of high voltage transistor, Pocket indicates a pocket implant, LDD indicates an LDD implant, Deep S/D indicates a deep S/D implant, and B, P, As and BF₂ indicate impurity ions. LN anneal denotes an annealing for an LDD, SW denotes an annealing for a sidewall and XP denotes an annealing for a deep S/D. Further, pf. designates a preferable value, and tilt (4R) indicates that an ion implantation target rotates 90 degrees four times, with performing each ¼ implantation of the total ion implantation amount.

As illustrated in example Table 1, the condition of deep S/D implant has become different as compared with the existing 0.13 μm device. This is to effectively control a short channel effect through a lateral diffusion of a deep S/D dopant as a gate length and a side spacer wall width are rapidly reduced as compared with the existing 0.13 μm device. That is, for an NMOS, a deep S/D implant may be performed, arsenic (As) heavier than the existing phosphorous (P) may be applied together. For a PMOS, a two step implant performed two times may be performed with boron (B). Further, implant energy of LDD implant LN, LP IMP may be reduced as compared with 0.13 μm device. An anneal process (LN anneal and SW anneal) may be performed after the LDD implant by a spike anneal. For example, the spike anneal may be preferably performed at a temperature between 950 to 1000° C. Also, an anneal process XP ANL performed after the deep S/D implant may be performed through a spike anneal. For example, the spike anneal may be performed at a temperature range between 1000 to 1100° C. Accordingly, a junction depth between drain and source can be effectively reduced, and a short channel effect can be effectively controlled by employing the spike anneal, as compared with the existing Rapid Thermal Process (RTP).

Example FIGS. 3 and 4 provide a comparison between a simulation result (represented as a hatched line) and a measurement result (represented as points of ∘, □, ▭ etc.) for an actual lot for Iₒₙ-I_{off} characteristic in a NMOS and PMOS, in accordance with embodiments. Here, Process of Record (POR) denotes a baseline process condition. As illustrated in example FIGS. 3 and 4, the simulation result well accords with the actual measurement result. Also, to improve the Iₒₙ-I_{off} characteristic, the E.O.T. of device should be lowered relatively more. “Target” represented in example FIGS. 3 and 4 provides a value necessary for matching to a characteristic of device proposed in the same industries. Subsequently, a performance change of device and a process optimization based on thickness of the poly gate and a gate oxide process, that is, optimization of a gate stack, is described as follows.

In the performance of a MOSFET, a gate stack constructed of a poly gate and a gate oxide may have a kernel structure deciding a performance of device. This is why the gate stack decides a threshold voltage of the device and a great portion of the Iₒₙ-I_{off} characteristic. For a development of a 90 nm device process, a thickness optimization of poly gate and an optimization for a gate oxide formation process including a plasma nitridation may be performed.

Example FIGS. 5 and 6 each offer Iₒₙ-I_{off} characteristics of NMOS and PMOS based on a gate poly thickness in accordance with embodiments. Here, ▭, ∘ and □ each designate 50 nm n, 65 nm, 80 nm for gate lengths, and width 10 μm indicates 10 μm for an active width. An experiment for two conditions of 1500 Å and 1300 Å in the gate poly thickness is performed. As illustrated in example FIGS. 5 and 6, in a performance change of a device based on the gate poly thickness, the NMOS is more sensitive in comparison with the PMOS. This may result from a dopant difference of deep S/D of the NMOS and the PMOS. It means that for the NMOS, relatively heavy phosphorous and arsenic may be applied to the deep S/D implant process, and an activation of dopants of gate poly in a subsequent spike anneal process and a doping profile in gate poly and gate oxide interface are sensitive according to a difference of gate poly thickness. On the other hand, for the PMOS, a dopant of deep S/D is boron, and a sufficient activation happens passing through a spike anneal process unlike the NMOS, thereby maintaining a relatively high doping concentration in the gate poly and the gate oxide interface. That is, the NMOS has a relatively more sensitive influence on the E.O.T. as compared with the PMOS according to the activation and dopant used in the deep S/D implant process.

Example FIG. 7 illustrates a threshold voltage distribution of a long channel device based on a gate poly thickness in accordance with embodiments. Here, 10/10 Transistor indicates an active width/gate length of transistor. As illustrated in example FIG. 7, with the results of example FIGS. 5 and 6, there is provided a cumulative distribution of threshold voltage Vₜ of a long channel device based on a gate poly thickness. For example, when lowering the thickness of the gate poly, a penetration effect of the dopant of the poly gate into the substrate may be generated in the deep S/D implant and a subsequent activation process. Therefore, a threshold voltage distribution of a MOSFET device is undesirable. As illustrated in example FIG. 7, in a PMOS there is no difference between a Vₜ distribution of a transistor with a gate poly having 1300 Å thickness and Vₜ distribution of a transistor with a gate poly having 1500 Å thickness. For an NMOS, Vₜ of a transistor with a gate poly of 1300 Å thickness is lower than Vₜ of a transistor with a gate poly of 1500 Å thickness. This is why E.O.T. can be effectively lowered in the gate poly having 1300 Å thickness than one having 1500 Å thickness as described above.

Example FIGS. 8 and 9 each provide Iₒₙ-I_{off} characteristics of an NMOS and a PMOS based on a nitrogen content in a plasma nitridation DPN process in accordance with embodiments. Here, 10/0.065 indicates an active width/gate length. As illustrate in example FIGS. 8 and 9, a characteristic change of the NMOS and the PMOS based on the nitrogen content shows an opposite tendency (refer to arrow). This is concerned with a phenomenon that nitrogen penetrates into the substrate in the plasma nitridation process to restrain a diffusion of boron. That is, the phenomenon results from that as the concentration of nitrogen penetrating into the substrate becomes high, the diffusion of boron in the channel area of the NMOS and boron in the deep S/D area of the PMOS is restrained. In accordance with embodiments, a 90 nm device may have a gate stack structure of a gate poly with a thickness in a range of between 1150 to 1450 Å, preferably 1300 Å, a gate dielectric that employs a thermal oxide having a thickness in a range of between 14 to 18 Å, preferably 16 Å, and a plasma nitridation of nitrogen at a concentration in a range of between 8 to 12%, preferably 10%, by considering a deep S/D implant condition and a poly depletion etc.

Optimization for the pocket implant process and the deep S/D implant process is described as follows. In a CMOSFET device, the pocket implant process significantly influences the performance of device. The pocket implant is a process to overcome a short channel effect becoming serious as a gate length L_{g} becomes shortened. The pocket implant is closely concerned with a threshold voltage (Vₜ) roll-off characteristic based on a gate length of a device and a band-to-band tunneling characteristic etc. Furthermore, the deep S/D implant process may be related to a short channel effect and punch-through, junction leakage etc. Particularly, since the poly gate may be doped together in the deep S/D implant process, the deep S/D implant process may be a very significant process.

Example FIG. 10 provides an Iₒₙ-I_{off} characteristic of a device based on an implant dosage in a pocket implant process in accordance with embodiments where ▭, ∘ and □ individually indicate 50 nm, 65 nm and 80 nm for gate lengths, respectively. Example FIG. 11 represents a Vₜ roll-off characteristic of a device based on an implant dosage in a pocket implant process in accordance with embodiments, in which a transverse axis indicates a gate length and a longitudinal axis denotes Vₜ. Adjacent the direction of the arrow in the drawing, a dose amount increases.

As illustrated in example FIG. 10, the lower the pocket implant dosage, the Iₒₙ-I_{off} characteristic of the device increases. As illustrated in example FIG. 11, Vₜ of a long channel device may be altered according to the pocket implant dosage. As illustrated in the results of example FIGS. 10 and 11, it may be appreciated that the pocket implant dose affects the E.O.T. of the device. Meaning, a gate poly exposed in the pocket implant process may be counter-doped by a pocket implant dopant. Thereby, net doping concentration of a gate poly and a gate oxide interface becomes different, affecting the E.O.T. Through such a phenomenon, as illustrated in example FIG. 11, threshold voltage Vₜ of a long channel device increases together as the pocket implant dosage increases. As described above, the reason why threshold voltage Vₜ of the long channel device increases together is that the pocket implant process of a relatively high dosage becomes a factor of increasing the E.O.T. of the device.

Example FIGS. 12 and 13 individually provide an Iₒₙ-I_{off} characteristic of a device based on a deep S/D implant dose and a deep S/D implant energy in a deep S/D implant process for an NMOS and a PMOS in accordance with embodiments where ▭, ∘ and □ each indicate 50 nm, 65 nm and 80 nm for gate lengths, respectively. The deep S/D implant process may be a very significant process deciding not only a short channel effect and a leakage characteristic of the device but also the equivalent oxide thickness (E.O.T.). As illustrated in example FIGS. 12 and 13, it may be appreciated that as a deep S/D implant dosage increases, an Iₒₙ-I_{off} characteristic of the NMOS or the PMOS device may be enhanced. The reason for this phenomenon is that as the deep S/D implant dosage and the implant energy increase, a doping concentration of the gate poly increases and the E.O.T. in an operation of the device is lowered. However, a lateral diffusion of dopants may increase in a subsequent anneal process by an increase of the deep S/D implant dosage and a punch-through between the source and drain.

A gate pre-doping process for optimization of a spike anneal process and a performance improvement of an NMOS is described as follows. An anneal (XP anneal) process after a deep S/D implant process may be closely concerned with not only a lateral diffusion of the deep S/D dopant and activation, but also an activation of the dopant within the gate poly. In a 90 nm device in accordance with embodiments, to effectively reduce a junction depth Xⱼ between the source and drain and to control a lateral diffusion of the dopant implanted in the source/drain, a spike anneal process may be employed. The spike anneal process may have a ramping-up rate of between 150 to 350° C./sec, preferably 250° C./sec in a spike annealing temperature and a ramping-down rate of between 25 to 125° C./sec, preferably 75° C./sec in the spike annealing temperature. Meaning, a heat treatment time is shortened as compared with the existing RTP process. The spike anneal process may be performed at a temperature range of between 1000 to 1100° C.

Example FIGS. 14 and 15 each provide an Iₒₙ-I_{off} characteristic of an NMOS and a PMOS by temperature of a spike anneal process in accordance with embodiments where ▭, ∘ and □ each indicate 50 nm, 65 nm and 80 nm for gate lengths, respectively. As illustrated in example FIGS. 14 and 15, as the temperature of spike anneal process increases, an electrical characteristic of the device is enhanced. The reason for this phenomenon is that an activation of dopants within the gate poly may be performed more smoothly in the spike anneal process at high temperature. Particularly in the NMOS, the on-current Iₒₙ increases without increasing leakage current in the spike anneal process at a relatively high temperature. This means that the spike anneal process at the relatively high temperature may be appropriate for a performance improvement of the device.

Example FIG. 16 illustrates a gate pre-doping process for a device performance improvement of an NMOS in accordance with embodiments. The semiconductor device illustrated in example FIG. 16 may include semiconductor substrate 10 (or well), shallow trench isolation (STI) 18 formed in substrate 10, gate dielectric 12 formed on and/or over semiconductor 10 and STI 18, gate poly 14 formed on and/or over gate dielectric and photoresist pattern 16 formed on and/or over gate poly 14. As illustrated in example FIG. 16, in the gate pre-doping process, a deposition may be performed until gate poly 14 and then only an NMOS area is selectively exposed through use of photoresist (PR) mask 16 (Deep S/D mask of NMOS). After that, phosphorous ion at a relatively high dosage may be implanted by using ion implantation mask 16. The process may be applied since the E.O.T. cannot be effectively lowered only with a deep S/D implant process of NMOS. By the process, a poly depletion effect of the NMOS may be controlled by increasing a doping concentration of gate poly 14 of the NMOS, and the E.O.T. of the device can be effectively reduced. In addition, through such a process, a deep S/D implant dosage of the NMOS can be reduced. When the deep S/D implant dosage of the NMOS is reduced, a depth of the deep S/D may be shortened, and therefore, an isolation between the PMOS and the NMOS can become enhanced.

Example FIG. 17 provides an Iₒₙ-I_{off} characteristic comparison for an NMOS (represented as ∘) to which a gate pre-doping process is applied in accordance with embodiments and an NMOS (represented as ▭) to which the gate pre-doping process is not applied. As illustrated in example FIG. 17, an electrical characteristic of the NMOS to which the gate pre-doping is applied, improves 30% or more than the device to which the gate pre-doping process is not applied. As described above, the reason for the phenomenon is that the E.O.T. of NMOS device can be effectively lowered by using the gate pre-doping. An electrical characteristic of the semiconductor device fabricated in a method in accordance with embodiments is described as follows. Example Table 2 illustrates an electrical characteristic Iₒₙ, I_{off} and Vₜ of a 90 nm logic transistor in accordance with embodiments. As illustrated in Table 2, the electrical characteristic for each NMOS and PMOS is satisfied for target values.

TABLE 2

| | NMOS | | PMOS | |
|---|---|---|---|---|
| | Embodiment | Target Value | Embodiment | Target Value |
| Vₜ (V) | 0.35 | 0.347 | −0.33 | −0.322 |
| Iₒₙ | 640 | 640 | 239 | 244 |
| (μA/μm) | | | | |
| I_{off} | 11800 | 10790 | 3400 | 3151 |
| (pA/μm) | | | | |

Example FIGS. 18 and 19 each provide a measurement result of gate leakage current in a 90 nm logic transistor for an NMOS and a PMOS in accordance with embodiments. A transverse axis indicates a result obtained by deducting Vₜ from a gate voltage V_{g}, and a longitudinal axis denotes a gate voltage. 10/10 Transistor designates active width/gate length of transistor. As illustrated in example FIGS. 18 and 19, the measurement of gate leakage current may be performed by a general measurement method of gate leakage current of the 90 nm logic transistor used in the same industries. The gate leakage current in an inversion state satisfies a condition of gate leakage current of 90 nm generic logic transistor used in the same industries. As described above, in accordance with embodiments, a process optimization of a pocket implant, deep S/D implant, spike anneal etc. and a gate pre-doping process for a device performance improvement of the NMOS are provided.

Example FIG. 20 is a flowchart for a semiconductor device fabrication method in accordance with embodiments while example FIG. 21 offers a performance of an NMOS manufactured in a semiconductor device fabrication method in accordance with embodiments. As illustrated in example FIG. 21, reference numeral 200 indicates an example of applying DPN to a thick poly gate, reference numeral 202 an example of applying DPN to a thin poly gate, reference numeral 204 an example of increasing dosage of a pocket implant process, reference numeral 206 an example of additionally performing a spike anneal process, and reference numeral 208 an example of additionally performing an N+ pre-gate doping implant process.

As illustrated in example FIG. 20, in the semiconductor device fabrication method in accordance with embodiments, step 101 includes forming a well and a shallow trench isolation (STI) in the semiconductor substrate formed. In step S103, a gate oxide is formed on and/or over the well and the STI. In accordance with embodiments, in forming the gate oxide, nitrogen may be implanted in the gate oxide by using the plasma nitridation process. In step 105, a gate may then be formed on and/or over the gate oxide. In step 107, a pocket may be formed under the gate. A dosage of the pocket implant may be lowered. In step 109, a first spike anneal may then be performed on the semiconductor substrate. As an example, the first spike anneal may be performed at a temperature range of between 950 to 1000° C. The temperature of the first spike anneal may be increased at a ramping-up rate in a range between 150 to 350° C./second, preferably 250° C./second and temperature of the first spike anneal may be decreased by a ramping-down rate in a range between 25 to 125° C./second, preferably 75° C./second.

In step 111, a deep source/drain implant process may then performed on the semiconductor substrate. In step 113, a second spike anneal may then be performed on the semiconductor substrate. In the deep source/drain implant process, phosphorus, arsenic and phosphorus ions may be sequentially implanted in the NMOS area, and boron ions may be implanted in two sequentially steps in the PMOS area. The second spike anneal may be performed at a temperature range between 1000 to 1100° C. The temperature of the second spike anneal may be increased by a ramping-up rate in a range between of 150 to 350° C./second, preferably 250° C./second. The temperature of the second spike anneal may be decreased by a ramping-down rate in a range between 25 to 125° C./second, preferably 75° C./second. The temperature of the spike anneal may be relatively high.

In accordance with embodiments, after forming the gate, a gate pre-doping to implant dopants into only an NMOS area (i.e., an area on which NMOS is formed) may be further performed. Dopants implanted into the NMOS area may be phosphorus, and in performing the gate pre-doping, dopants may be implanted by using the same mask as the deep source/drain implant process performed for the NMOS area. Characteristics of the semiconductor device manufactured by a method of fabricating a semiconductor device in accordance with embodiments can thereby be enhanced.

A 90 nm logic transistor may be manufactured in accordance with embodiments through a simplified process as compared with the process for a 90 nm logic transistor employing indium channel and multi-pocket of the same industries. Additionally, in accordance with embodiments, an SRAM cell smaller than 6T (six transistors) SRAM cell of the same industries can be realized. In accordance with embodiments, a process change caused by an indium doping does not occur by not employing an indium channel. Further, by not employing a multi pocket, the process can be simplified. Meaning, the process in accordance with embodiments can be relatively more simplified and simultaneously the same or better device characteristic may be realized as compared with a device characteristic proposed in the same industries. In accordance with embodiments, as a critical dimension (CD) becomes smaller, ArF (193 nm) scanner may be used in a photolithography process. Therefore a spacer process performed in forming the existing STI can be omitted. Also, for a gap fill of the STI area, a Deposition/Wet/Deposition (D/W/D) process may be used.

Through such a process, the STI gap fill narrower and deeper than the existing device can be obtained. To effectively lower the E.O.T. in a gate stack, a plasma nitridation process capable of adding nitrogen of high concentration is applied after forming a gate oxide formation. In order to reduce a performance fall of a device caused by poly depletion, a gate poly thickness may be reduced. This is for effectively doping the gate poly as implant energy becomes lower in the deep S/D implant process. Further, in a side spacer wall formation process, a remaining oxide process with oxide remaining unlike the existing process totally etching oxide is applied. In employing the remaining oxide process, an STI loss can be prevented in an oxide etch of side spacer wall process. Such principal processes in an embodiment of the invention are summarized as the following example Table 3.

TABLE 3

| Process | Feature | Remark | |
|---|---|---|---|
| Litho. | ArF scanner | | AA, GC, M1C-D4 |
| | (193 nm) | | |
| STI (depth/width) | 350/150 | D/W/D process for | |
| (nm) | | gap fill | |
| Gate length (nm) | 65 nm (on TEM) | | |
| Poly height (nm) | 130 | NMOS Pre doping | |
| E.O.T (Å) | 23/25 (N/P) | 16 Å pure oxide + | plasma nitridation |
| | | 10% plasma | |
| | | nitridation | |
| Sidespacer wall width | 70 | O/N/O = 200/200/350 | Remain oxide scheme |
| (nm) | (ONO) | | |
| Dopant Activation | Spike RTP | | LDD, S/D |
| Salicide | Cobalt | 120 Å | |
| Spacer RIE | Remain oxide | 100 Å on Active | No Si loss |

As illustrated in example Table 3, AA indicates active, GC indicates a gate, M1C a contact, and D4 as metal of D1 to D4. The data provided in example Table 1 are preferable values. For example, depth of the STI may be in a range between 290 to 403 nm, and a width of the STI may be in a range between 127 to 225 nm. A gate length may be in a range between 60 to 70 nm, the thickness (height) of the gate poly may be in a range between 115 to 145 nm, E.O.T. of the NMOS may be in a range between 21 to 25 Å, and E.O.T. of the PMOS may be in a range between 23 to 27 Å. Pure gate oxide may have a thickness in a range between 14 to 20 Å, the width of a sidewall spacer may be in a range between 60 to 80 nm, and the remaining oxide may have a thickness in a range between 50 to 150 Å.

As described above, in a semiconductor device fabrication method in accordance with embodiments, performance of devices can increase and the processes can be simplified.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a well in a semiconductor substrate; and then
forming a gate oxide on the semiconductor substrate; and then
forming a gate on the gate oxide; and then
forming a pocket under the gate; and then
performing a first spike anneal on the semiconductor substrate; and then
performing a deep source/drain implant process on the semiconductor substrate; and then
performing a second spike anneal on the semiconductor substrate.

2. The method of claim 1, wherein forming the gate oxide comprises implanting nitrogen at a range between 8 to 12% in the gate oxide using a plasma nitridation process.

3. The method of claim 1, wherein the first spike anneal is performed at a temperature in a range between 950 to 1000° C.

4. The method of claim 3, wherein performing the first spike anneal comprises increasing the temperature at a ramping-up rate in a range between 150 to 350° C./second and then decreasing the temperature at a ramping-down rate in a range between 25 to 125° C./second.

5. The method of claim 1, wherein the second spike anneal is performed at a temperature in a range between 1000 to 1100° C.

6. The method of claim 5, wherein performing the second spike anneal comprises increasing the temperature at a ramping-up rate in a range between 150 to 350° C./second and then decreasing the temperature at a ramping-down rate in a range between 25 to 125° C./second.

7. The method of claim 1, wherein performing the deep source/drain implant process comprises sequentially implanting a first plurality of phosphorus ions, a plurality of arsenic ions and a second plurality of phosphorus ions in forming an NMOS.

8. The method of claim 7, wherein performing the deep source/drain implant process comprises sequentuially implanting the first plurality of phosphorus ions with an energy in a range between 25 to 35 KeV and a dosage amount in a range between 5.1E13 to 6.9E13, the plurality of arsenic ions with an energy in a range between 25 to 35 KeV and a dosage amount in a range between 1.6E15 to 2.3E15, and the second plurality of phosphorus ions with an energy in a range between 6.5 to 9.5 KeV and a dosage amount of between 0.85E15 to 1.15E15.

9. The method of claim 1, wherein performing the deep source/drain implant process comprises sequentially implanting a first plurality of boron ions and a second plurality of boron ions in forming a PMOS.

10. The method of claim 9, wherein performing the deep source/drain implant process comprises implanting the first plurality of boron ions with an energy in a range between 8.5 to 11.5 KeV and a dosage amount in a range between 4.2E13 to 5.8E13, and then the second plurality of boron ions with an energy in a range between 3.4 to 4.6 KeV and a dosage amount in a range between 2.2E15 to 3.0E15.

11. The method of claim 1, further comprising, after forming the gate, performing a gate pre-doping by implanting dopants only into an NMOS area.

12. The method of claim 11, wherein the dopant implanted into the NMOS area is phosphorus.

13. The method of claim 11, wherein performing the gate pre-doping comprises implanted dopants by using the same mask as used in the deep source/drain implant process performed in an NMOS area.

14. The method of claim 1, wherein the gate is formed with a thickness in a range between 1150 to 1450 Å.

15. The method of claim 1, wherein the gate oxide is formed with a thickness in a range between 14 to 18 Å.

16. A method comprising:
forming a well in a semiconductor substrate; and then
forming a gate structure on the semiconductor substrate; and then
forming a pocket under the gate structure; and then
performing a first spike anneal on the semiconductor substrate; and then
performing a deep source/drain implant process on the semiconductor substrate by sequentuially implanting a first plurality of phosphorus ions, a plurality of arsenic ions and a second plurality of phosphorus ions in an NMOS area of the semiconductor substrate and sequentially implanting a first plurality of boron ions and a second plurality of boron ions in a PMOS area of the semiconductor substrate; and then
performing a second spike anneal on the semiconductor substrate.

17. The method of claim 16, wherein forming the gate structure comprises:
forming a gate oxide on the semiconductor substrate by implanting nitrogen in an oxide film using a plasma nitridation process; and then
forming a gate on the gate oxide.

18. The method of claim 17, wherein the gate is formed with a thickness in a range between 1150 to 1450 Å.

19. The method of claim 16, wherein the gate oxide is formed with a thickness in a range between 14 to 18 Å.

20. A method comprising:
forming a well in a semiconductor substrate; and then
forming a gate structure on the semiconductor substrate; and then
performing a gate pre-doping by implanting ions of a first-type dopant into an NMOS area of the semiconductor substrate; and then
forming a pocket under the gate structure; and then
performing a first spike anneal on the semiconductor substrate; and then
performing a deep source/drain implant process on the semiconductor substrate by sequentuially implanting ions of the first-type dopant, ions of a second of a second-type dopant and ions of the first-type dopant in the NMOS area and sequentially implanting ions a third-type dopant and ions of the third-type dopant in a PMOS area of the semiconductor substrate; and then
performing a second spike anneal on the semiconductor substrate.
